(19) United States
(12) Patent Application Publication
(10) Pub. No.: US 2012/0298951 A1
(43) Pub. Date: Nov. 29, 2012

(54) Optoelectronic Semiconductor Body with a Quantum Well Structure

(75) Inventors: Tobias Meyer, Ihrlerstein (DE); Matthias Peter, Regensburg (DE); Rainer Butendeich, Regensburg (DE); Tetsuya Taki, Yokohama (JP); Juergen Off, Regensburg (DE); Alexander Walter, Laaber (DE)

(73) Assignee: OSRAM Opto Semiconductors GmbH, Regensburg (DE)

(21) Appl. No.: 13/386,861

(22) PCT Filed: Jul. 22, 2010
(86) PCT No.: PCT/EP2010/060658

§ 371 Date: Jul. 5, 2012

(30) Foreign Application Priority Data
Jul. 24, 2009 (DE) 10 2009 034 588.4
Sep. 7, 2009 (DE) 10 2009 040 438.4

(51) Int. Cl. H01L 33/04

(52) U.S. Cl. 257/13; 257/E33.008

(57) ABSTRACT

An optoelectronic semiconductor body is provided, which contains a semiconductor material which is composed of a first component and a second component different from the first component. The semiconductor body comprises a quantum well structure, which is arranged between an n-conducting layer (1) and a p-conducting layer (5). The quantum well structure consists of following elements: one single quantum well layer 31 or a layer stack (3), which consists of a plurality of quantum well layers (31) and at least one barrier layer (32), one barrier layer (32) being arranged between each pair of successive quantum wall layers (31), which barrier layer adjoins both quantum wall layers (31); an n-side terminating layer (2), which adjoins the n-conducting layer (1) and the single quantum well layer (31) or the layer stack (3); and a p-side terminating layer (4), which is arranged between the p-conducting layer (5) and the single quantum well layer (31) or the layer stack (3) and adjoins the layer stack (3) or the single quantum well layer (31).

The present application relates to an optoelectronic semiconductor body with a quantum well structure.

It is an object of the present application to provide an optoelectronic semiconductor body which has a particularly low forward voltage.

This object is achieved by an optoelectronic semiconductor body according to the independent claims. Advantageous configurations and further developments of the semiconductor body are indicated in the dependent claims. The disclosure content of the claims is hereby incorporated explicitly in the description by reference.

An optoelectronic semiconductor body is provided. The optoelectronic semiconductor body is a light-emitting diode or a laser diode, for example. The semiconductor body comprises an n-conducting layer and a p-conducting layer, between which a quantum well structure is arranged. The quantum well structure is conveniently provided to generate radiation and/or to receive electromagnetic radiation, in particular in the ultraviolet, visible and/or infrared spectral range.

The quantum well structure may be a single quantum well structure or a multiple quantum well structure. The single quantum well structure consists in particular of the following elements: one individual quantum well layer, an n-side terminating layer and a p-side terminating layer. The multiple quantum well structure consists in particular of the following elements: a layer stack, which consists of a plurality of quantum well layers and at least one barrier layer, an n-side terminating layer and a p-side terminating layer.

In the layer stack, a barrier layer is arranged between in each case two successive quantum well layers and adjoins the two quantum wall layers. In other words, the layer stack represents an alternating sequence of quantum wall layers and barrier layers, the stack being terminated on both sides by a quantum well layer. The layer stack thus contains n-quantum wall layers and n−1 barrier layers, n being a natural number greater than or equal to 2. In a further development, the number n of quantum wall layers is less than or equal to 10.

The respective barrier layers have in particular a uniform material composition. In other words, the material composition of the respective barrier layers remains in particular unchanged from one of the adjacent quantum wall layers to the other adjacent quantum well layer. A barrier layer of uniform material composition in particular does not contain a sequence of portions of different material composition.

If the semiconductor body comprises a multiple quantum well structure, the n-side terminating layer adjoins the layer stack and the n-conducting layer. The p-side terminating layer is arranged between the layer stack and the p-conducting layer and adjoins the layer stack. Preferably the p-side terminating layer also adjoins the p-conducting layer.

In other words, in a semiconductor body with a multiple quantum well structure the layer stack is arranged between the n-side terminating layer and the p-side terminating layer in such a way that, when viewed from the n-side of the semiconductor body, the n-side terminating layer adjoins the first quantum well layer of the layer stack and the p-side terminating layer adjoins the last quantum well layer of the layer stack.

If the semiconductor body has a single quantum well structure, the n-side terminating layer adjoins the single quantum well layer and the n-conducting layer. The p-side terminating layer is arranged between the single quantum well layer and the p-conducting layer and adjoins the single quantum well layer. Preferably the p-side terminating layer also adjoins the p-conducting layer.

The optoelectronic semiconductor body, in particular at least the quantum well structure, the n-conducting layer and the p-conducting layer, contains a semiconductor material, which is composed of a first component and a second component different from the first component. In this case, not all the layers of the semiconductor body have to contain the first component of the semiconductor material. Preferably, however, the first component is contained at least in the quantum well layer(s), in the barrier layer(s) when applicable, the n-side terminating layer and the p-side terminating layer. The composition of the second component does not have to be the same in all the layers of the semiconductor body. For example, the second component may contain a plurality of elements, which are present in the second component in different mole fractions in different layers of the semiconductor body.

The semiconductor material is for example a hexagonal compound semiconductor material. A hexagonal compound semiconductor material has a hexagonal lattice structure. For example, the hexagonal compound semiconductor material is a binary, ternary and/or quaternary compound of elements of the main groups II and VI of the periodic table of chemical elements. It may for example be one of the following compounds: ZnO, ZnMgO, CdS, ZnCdS, MgBeO. Alternatively, the hexagonal compound semiconductor material may be a binary, ternary and/or quaternary compound of elements of main groups III and V, for example a nitride compound semiconductor material. It may for example be one of the following semiconductor structures: BN, AlGaN, GaN, InAlGaN.

In this case, it is not mandatory for the semiconductor material to have a mathematically exact composition according to one of the above formulae. Instead, it may comprise one or more dopants and additional constituents. For simplicity's sake, however, the above formulae include only the fundamental constituents of the crystal lattice, even if these may in part be replaced by relatively small quantities of further substances.

The mole fraction of the first component of the semiconductor material is greater in each of the quantum wall layers than in the n-side terminating layer, in the p-side terminating layer and, when applicable, in the barrier layer or in the barrier layers of the layer stack. In this way, a band structure of the quantum well structure is in particular achieved, in which the quantum well structure has a smaller band gap in the region of the quantum wall layers than in the region of the n-side terminating layer, the p-side terminating layer and the barrier layer(s), as the case may be. In one configuration the mole fraction of the first component is of equal magnitude in all the quantum wall layers.

The mole fraction of the first component is greater in the n-side terminating layer than in the n-conducting layer. In the p-side terminating layer the mole fraction of the first component is preferably greater than in the p-conducting layer.

In the case for example of a semiconductor body which contains a hexagonal compound semiconductor material, for instance in the case of a semiconductor body based on the III/V semiconductor material system InAlGaN, i.e. InxAlyGal-x-yN with 0≦x≦1, 0≦y≦1 and x+y≦1, piezoelectric fields occur in the quantum well structure. The piezoelectric fields constitute energetic barriers for the charge carriers moving in the quantum well structure.

These charge carrier barriers arise, in particular due to the polar wurtzite crystal structure, if strain arises in the semiconductor material in the event of changes in the mole fraction of the first component, i.e. in this case in the event of a change in the In fraction.

The inventors have discovered that with the semiconductor body according to the present application these barriers are particularly low, such that the semiconductor body has a particularly low forward voltage. For example, the forward voltage is reduced relative to semiconductor bodies in which the n-side terminating layer and/or the p-side terminating layer lack the first component of the semiconductor body. The forward voltage is also advantageously reduced relative to a semiconductor body in which a further layer containing the first component of the semiconductor material in a smaller mole fraction than the n-side terminating layer is arranged for example between the n-side terminating layer and the first quantum well layer of the layer stack, or the single quantum well layer.

In one configuration the semiconductor body has an emission maximum at a wavelength of greater than or equal to 440 nm, preferably of greater than or equal to 460 nm, particularly preferably of greater than or equal to 480 nm. For example, the emission maximum is in the green spectral range. In one configuration the wavelength of the emission maximum is less than or equal to 1400 nm.

As the wavelength of the emission maximum increases, the band gap of the quantum well layer(s) decreases, whereby in principle the forward voltage should also fall. In order to reduce the band gap, the mole fraction of the first component of the semiconductor material in the quantum wall layers or in the single quantum well layer is increased, however. In the case of conventional light-emitting diodes of InAlGaN, this leads to such an increase in charge carrier barriers that the forward voltage is virtually independent of the emission wavelength.

In contrast, the distribution of the charge carrier barriers to the junction between the n-conducting layer and the n-side terminating layer and to the junction between the n-side terminating layer and the single quantum well layer or the first quantum well layer in the case of the semiconductor body according to the present application has a particularly advantageous effect if the mole fraction of the first component in the quantum well layer(s) is large. The reduction in the forward voltage achievable with the semiconductor body according to the present application is therefore particularly pronounced at higher wavelengths.

According to another configuration the mole fraction of the first component of the semiconductor material in the barrier layer or in the barrier layers is at least as great as in the n-side terminating layer. According to a further configuration, the mole fraction of the first component of the semiconductor material in the barrier layer or in the barrier layers is alternatively or additionally at least as great as in the p-side terminating layer.

The mole fraction of the first component may be of equal magnitude in the n-side terminating layer and in the p-side terminating layer. It is also feasible for the mole fraction of the first component in the n-side terminating layer to have a different value from in the p-side terminating layer. The mole fraction of the first component of the semiconductor material in the barrier layer(s) is preferably at least as great as the greater of the mole fractions of the first component in the n-side terminating layer and in the p-side terminating layer.

For example, the mole fraction of the first component of the semiconductor material in the barrier layer or the barrier layers has a value which is between the mole fraction of the first component in the quantum wall layers and the greater of the mole fractions of the first component in the n-side terminating layer and in the p-side terminating layer. In another configuration the mole fraction of the first component of the semiconductor material is of equal magnitude in the n-side terminating layer, in the barrier layer or the barrier layers and in the p-side terminating layer.

In the present context, a “mole fraction of equal magnitude” of the first component in two layers is understood to mean that the mole fraction—in particular the mole fraction averaged over the thickness of the respective layer—of the first component differs by 5% or less between the layers. In other words, the mole fraction in the second of the two layers is in a range between 0.95 times the mole fraction in the first of the two layers and 1.05 times of the mole fraction in the first layer. Preferably, the mole fraction differs by 1% or less, particularly preferably by 0.5% or less.

The forward voltage may advantageously be further reduced in this way. For example, the forward voltage may be reduced relative to a semiconductor body in which the barrier layer(s) lack the first component of the semiconductor body or which comprises a plurality of barrier layers with different fractions of the first component between two successive quantum wall layers.

According to one configuration the n-conducting layer comprises a p-side boundary zone and the n-side terminating layer comprises an n-side boundary zone. The p-side boundary zone of the n-conducting layer and the n-side boundary zone of the n-side terminating layer adjoin one another. In particular, they have a common interface. The p-side boundary zone of the n-conducting layer and the n-side boundary zone of the n-side terminating layer are for example doped with an n-dopant. The n-dopant is for example silicon. In the p-side boundary zone of the n-conducting layer below the n-side boundary zone of the n-side terminating layer the n-dopant is present for example in a concentration of greater than or equal to 5×1018 atoms/cm³. For example, the concentration of the n-dopant amounts to between 5×1018 atoms/cm³ and 5×1019 atoms/cm³, inclusive of the limit values. The n-dopant in particular advantageously reduces the piezoelectric barrier, which forms between the n-conducting layer and the n-side terminating layer, such that the forward voltage of the semiconductor body is further reduced.

In a further configuration the n-side terminating layer comprises a p-side boundary zone, which adjoins the single quantum well layer or the layer stack, in particular has a common boundary surface with the first quantum well layer, and is nominally undoped. This reduces the risk of the n-dopant impairing the emission characteristics and/or radiation receiving characteristics of the quantum well structure.

That the boundary zone is “nominally undoped” is understood in the present context to mean that the boundary zone is undoped or slightly n-doped. “Slightly n-doped” here means that the concentration of the n-dopant is at most 0.1 times, preferably at most 0.05 times and in particular at most 0.01 times the concentration of the n-dopant in an n-doped region, in particular in the n-doped boundary zone of the n-side terminating layer. The concentration of the n-dopant in the nominally undoped region is for example less than or equal to 1×1018 atoms/cm³, preferably less than or equal to 5×1017 atoms/cm³, in particular it is less than or equal to 1×1017 atoms/cm³.

In one configuration the n-side terminating layer has a layer thickness of greater than or equal to 10 nm, for example of greater than or equal to 50 nm. In a further development the p-side boundary zone has a layer thickness of greater than or equal to 10 nm, preferably of greater than or equal to 50 nm. Such layer thicknesses are particularly advantageous for reducing the forward voltage.

In one further development the n-side terminating layer has a layer thickness of less than or equal to 120 nm. Larger layer thicknesses of the n-side terminating layer increase the risk of a satisfactory crystal quality not being achieved when producing the quantum well structure.

In one configuration the first component of the semiconductor material is formed of In. The second component of the semiconductor material is for example formed of nitrogen and at least one material from the group consisting of Al and Ga. The semiconductor material is for example InxAlyGal-x-yN. The first component formed of In is present in the n-side terminating layer in a fraction x≧0.05, for example. The fraction x corresponds in particular to the mole fraction of In or is at least proportional thereto.

In one configuration the n-conducting layer lacks the first component of the semiconductor material. In a further configuration the p-conducting layer lacks the first component of the semiconductor material. In these configurations in particular the n-conducting layer and/or the p-conducting layer consist of the second component of the semiconductor material.

In a further configuration the mole fraction of the first component of the semiconductor material increases continuously or in a number of steps from the n-conducting layer towards the layer stack (or, in the case of a single quantum well structure, towards the single quantum well layer) within the n-side boundary zone of the n-side terminating layer. In this way, the piezoelectric barrier formed is particularly weak, such that the achievable forward voltage is particularly low.

Further advantages and advantageous configurations and further developments of the optoelectronic semiconductor body result from the following exemplary embodiment illustrated in conjunction with the figures, in which:

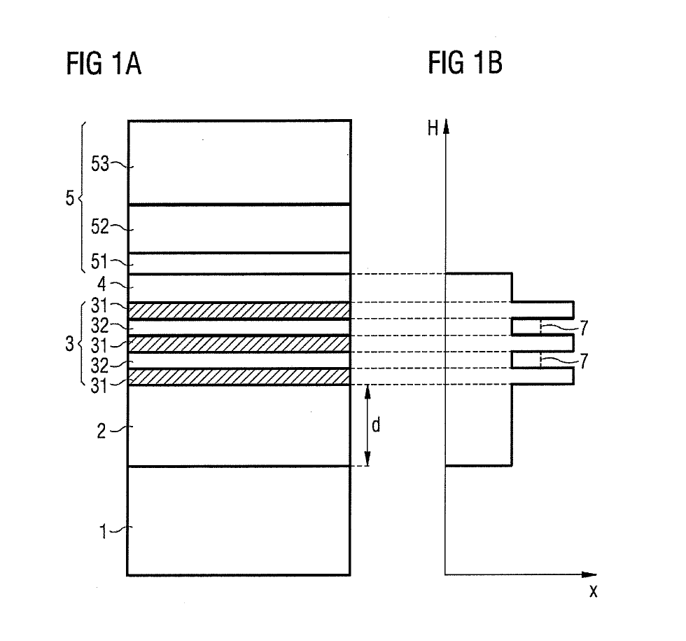

FIG. 1A is a schematic cross-section through an optoelectronic semiconductor chip according to a first exemplary embodiment,

FIG. 1B is a schematic representation of the fraction of the first component of the semiconductor material in the semiconductor body according to the exemplary embodiment of FIG. 1A,

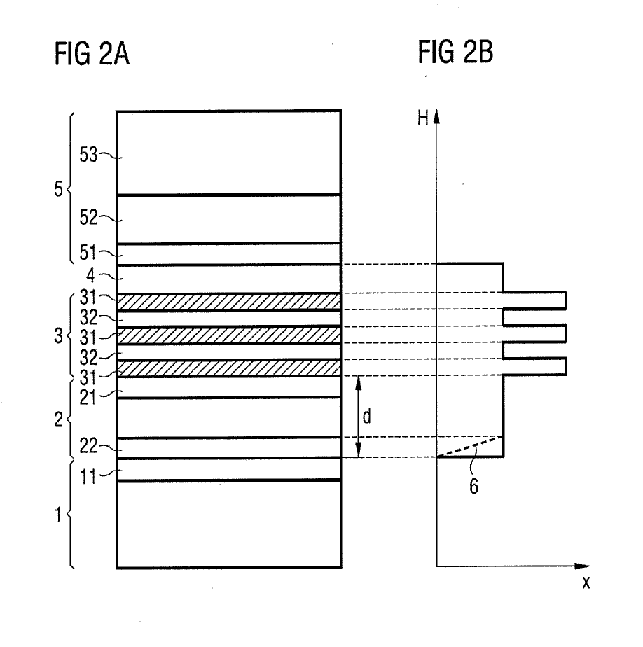

FIG. 2A shows a schematic cross-section through an optoelectronic semiconductor body according to a second exemplary embodiment, and

FIG. 2B is a schematic representation of the fraction of the first component of the semiconductor material in the optoelectronic semiconductor body according to FIG. 2B, and

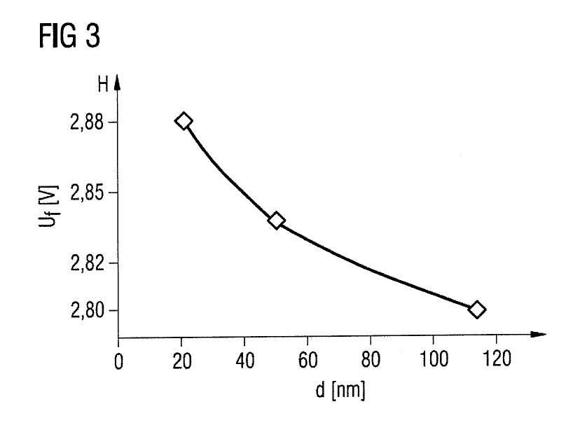

FIG. 3 shows the forward voltage of the optoelectronic semiconductor body according to the first exemplary embodiment as a function of the layer thickness of the n-side terminating layer.

In the exemplary embodiments and figures, identical or similar components or similarly acting components are in each case provided with the same reference numerals. The Figures should not be regarded as being true to scale. Instead, individual elements such as for example layers are shown exaggeratedly large, in particular exaggeratedly thick, to make the figures easier to understand and/or represent.

FIG. 1A shows a schematic cross-section through an optoelectronic semiconductor body according to a first exemplary embodiment.

The optoelectronic semiconductor body consists of the semiconductor material InxAlyGal-x-yN. It contains an n-conducting layer 1, which is in the present case a GaN layer doped with silicon as the n-dopant. On the opposite side from the n-conducting layer 1 the semiconductor body comprises a p-conducting layer 5.

In the present exemplary embodiment the p-conducting layer 5 has a multilayer structure. In the direction away from the n-conducting layer 1, it firstly comprises an undoped GaN layer 51. This is adjoined by a p-doped AlGaN layer 52. A p-doped GaN layer 53 is applied to the side of the p-doped AlGaN layer 52 remote from the n-conducting layer 1. The p-doped AlGaN layer 52 and/or the p-doped GaN layer 53 are doped for example with magnesium as the p-dopant. The structure of the n-conducting layer 5 is not limited to this multilayer structure, however.

A multiple quantum well structure is arranged between the n-conducting layer 1 and the p-conducting layer 5. This consists of an n-side terminating layer 2, a layer stack 3 and a p-side terminating layer 4.

The n-side terminating layer 2 adjoins the n-conducting layer 1 on the side remote from the layer stack 3. The p-side terminating layer 4 adjoins the n-conducting layer 5, here the GaN layer 51, on the side remote from the layer stack 3.

In the present case, the layer stack 3 consists of three quantum wall layers 31 and two barrier layers 32. The layer stack may however also contain another number n of quantum wall layers 31, i.e. n=2 or n≧4. It then contains n−1 barrier layers 32.

In the direction from the n-conducting layer 1 to the p-conducting layer 5, quantum well layers 31 and barrier layers 32 follow one another alternately. The layer stack 3 is terminated in each case towards the n-conducting layer 1 and towards the p-conducting layer 5 by a quantum well layer 31.

In this way, precisely one barrier layer 32 is arranged between each pair of successive quantum wall layers 31. On the n-side, i.e. towards the n-conducting layer 1, this barrier layer 32 adjoins the first of the two successive quantum wall layers 31. On the p-side, i.e. towards the p-conducting layer 5, this barrier layer 32 adjoins the second of the two successive quantum wall layers 31.

On the p-side the n-side terminating layer 2 adjoins a first quantum well layer 31 of the layer stack 3. On the n-side the p-side terminating layer 4 adjoins a last quantum well layer 31 of the layer stack 3.

It is also feasible for the optoelectronic semiconductor body to contain one single quantum well layer 31 instead of the layer stack 3. In this case the single quantum well layer has a layer thickness of for example 5 nm or more, preferably of 10 nm or more. If the semiconductor body contains a single quantum well layer 31, the n-side terminating layer 2 in particular adjoins the single quantum well layer 31 on the p-side and the p-side terminating layer 4 adjoins it on the n-side. The semiconductor body in this case in particular does not contain any barrier layers 32 between the terminating layers 2, 4 and the single quantum well layer 31.

FIG. 1B shows the fraction x of the first component of the semiconductor material of the semiconductor body, the first component being composed of In, as a function of the position H in the semiconductor body. The position H here in particular indicates the distance from the n-side major face of the n-conducting layer 1, when viewed from the n-conducting layer 1 towards the p-conducting layer 5. FIGS. 1A and 1B are on the same scale relative to the position H, such that each position on the H axis in FIG. 1B corresponds to a horizontal plane at the same height in the multilayer structure of FIG. 1.

The fraction x of the first component formed of In of the semiconductor material is greater in the quantum wall layers 31 than in the barrier layers 32, the n-side terminating layer 2 and the p-side terminating layer 4. The n-conducting layer 1 and the p-conducting layer 5 in this case do not—at least nominally—contain any indium.

The fraction x of the first component formed of In of the semiconductor material is of the same magnitude in the n-side terminating layer 2, in the barrier layers 32 and in the p-side terminating layer 4. It amounts for example to 0.05≦x≦0.25, for example x=0.05.

The change in the indium fraction x at the boundary surface between n-conducting layer 1 and n-side terminating layer 2 there brings about a first energetic charge carrier barrier as a result of piezoelectric fields. In this way a second energetic barrier arises at the boundary surface between the n-side terminating layer 2 and the first quantum well layer 31.

In contrast to conventional optoelectronic semiconductor bodies, the fraction of indium is already increased on the n-side of the first quantum well layer 31 by means of the n-side terminating layer. It is also not lowered again between the n-side terminating layer 32 and the first quantum well layer. Thus the jump in the indium fraction x between the n-side terminating layer 2 and the first quantum well layer 31 of the layer stack 3 is comparatively low in the present semiconductor body.

The entire barrier to be overcome by the charge carriers from the n-conducting layer 1 as far as the first quantum well layer 31 is particularly low due to the spatial separation between the first barrier at the boundary surface between n-conducting layer 1 and n-side terminating layer 2 and the second barrier at the boundary surface between n-side terminating layer 2 and first quantum well layer 31. This is likewise also true of charge carrier barriers on the p-side of the layer stack 3 between the last quantum well layer 31, which adjoins the p-side terminating layer 4 and the boundary surface between the p-side terminating layer 4 and the p-conducting layer 5.

In one variant of this exemplary embodiment the fraction x in the barrier layers 32 is greater than in the n-side terminating layer 2 and than in the p-side terminating layer 4. This is indicated in FIG. 1B by the dashed lines 7. In this way a particularly advantageous, in particular a particularly homogeneous charge carrier distribution between the individual quantum wall layers 31 may be achieved. In particular, particularly low piezoelectric barriers may be achieved between the individual quantum wall layers 31.

The inventors have found out that the achievable forward voltage is particularly low if the indium fraction x in the barrier layers 32 is at least as great as in the n-side terminating layer 2 and in the p-conducting terminating layer 4, for example if the indium fraction x is of equal magnitude in the n-side terminating layer 2, in the p-conducting terminating layer 4 and in the barrier layers 32. Additional barrier layers between successive quantum wall layers 31, which for example comprise a lower indium content or no indium, would disadvantageously increase the forward voltage of the semiconductor body.

The inventors have found out that the forward voltage Uf decreases as the thickness d of the n-side terminating layer 2 increases. This is illustrated by way of example in FIG. 3 for an optoelectronic semiconductor body which emits electromagnetic radiation with a emission maximum at a wavelength of 480 nm.

The forward voltage Uf decreases from 2.88 V at a layer thickness d of the n-side terminating layer 2 of 20 nm to a forward voltage Uf of 2.80 V at a layer thickness d of approx. 115 nm. Conventional InAlGaN semiconductor bodies with the same emission maximum wavelength have a forward voltage of approx. 3.0 V to 3.3 V.

The layer thickness d is preferably less than or equal to 120 nm, preferably less than or equal to 100 nm. The inventors have found out that with larger layer thicknesses d of the n-side terminating layer 2, the risk is increased that the crystal quality of the multiple quantum well structure is impaired.

FIGS. 2A and 2B show a schematic cross-section through an optoelectronic semiconductor body according to a second exemplary embodiment and the indium fraction x as a function of the position H in the semiconductor body, in a similar manner to the representation of the first exemplary embodiment in FIGS. 1A and 1B.

The semiconductor body according to the second exemplary embodiment differs from the semiconductor body of the first exemplary embodiment in that the n-side terminating layer 2 comprises an n-side boundary zone 22, which is doped with an n-dopant such as silicon and comprises a p-side boundary zone 21, which is nominally undoped.

The nominally undoped p-side boundary zone 21 adjoins the first quantum well layer 31 of the layer stack 3. The n-side boundary zone 22 is arranged on the side of the n-side terminating layer 2 remote from the layer stack 3 and adjoins a p-side boundary zone 11 of the n-conducting layer 1.

The p-side boundary zone 11 of the n-conducting layer 2 is likewise n-doped with the n-dopant, for example silicon. Here, as with the first exemplary embodiment, the entire n-conducting layer 1 is doped with silicon as the n-dopant.

In the p-side boundary zone 11 of the n-conducting layer 1 and the n-side boundary zone 22 of the n-side terminating layer 2 the n-dopant is present in a concentration of between 5×10¹⁸ atoms/cm³ and 5×10¹⁹ atoms/cm³, the limit values being included.

The inventors have found out that, by means of n-doping of the n-side boundary zone 22 of the n-side terminating layer 2, the energetic charge carrier barrier at the boundary surface between the n-conducting layer 1 and the n-side terminating layer 2, i.e. here at the boundary surface between the p-side boundary zone 11 of the n-conducting layer 1 and the n-side boundary zone 22 of the n-side terminating layer 2 may advantageously be further reduced. In the case for example of an optoelectronic semiconductor body in which the n-side terminating layer 2 has a layer thickness of d=20 nm and which has an emission maximum at a wavelength of 480 nm—corresponding to an energy gap of 2.58 electron-volts—the forward voltage Uf may be reduced from 2.88 V to for example 2.83 V, relative to the first exemplary embodiment.

In a variant of this exemplary embodiment the indium fraction x increases continuously within the n-doped, n-side boundary zone 22 of the n-side terminating layer 2 in the direction from the n-conducting layer 1 towards the layer stack 3, as indicated in FIG. 2B by the dotted line 6. In this way the energetic charge carrier barrier may be further reduced.

This patent application claims priority from German patent applications 102009034588.4 and 102009040438.4, whose disclosure content is hereby included by reference.

The description made with reference to exemplary embodiments does not restrict the invention to these embodiments. Rather, the invention encompasses any novel feature and any combination of features, even if this feature or this combination is not itself explicitly indicated in the exemplary embodiments or claims.

1. An optoelectronic semiconductor body, which contains a semiconductor material having a first component and a second component different from the first component, the semiconductor body comprising a multiple quantum well structure arranged between an n-conducting layer and a p-conducting layer, the multiple quantum well structure consisting of:
a layer stack, which consists of a plurality of quantum well layers and at least one barrier layer, one barrier layer being arranged between each pair of successive quantum wall layers, which barrier layer adjoins both quantum wall layers;
an n-side terminating layer, which adjoins the layer stack and the n-conducting layer; and
a p-side terminating layer, which is arranged between the layer stack and the p-conducting layer and adjoins the layer stack,
wherein the mole fraction of the first component of the semiconductor material
is greater in each of the quantum wall layers than in the n-side terminating layer, in the at least one barrier layer and in the p-side terminating layer, and
is greater in the n-side terminating layer than in the n-conducting layer and is greater in the p-side terminating layer than in the p-conducting layer.

2. The optoelectronic semiconductor body according to claim 1, wherein the n-conducting layer comprises a p-side boundary zone, which adjoins an n-side boundary zone of the n-side terminating layer, and the p-side boundary zone of the n-conducting layer and the n-side boundary zone of the n-side terminating layer are doped with an n-dopant, and
wherein the n-side terminating layer comprises a p-side boundary zone, which directly adjoins the layer stack and which is nominally undoped.

3. The optoelectronic semiconductor body according to claim 1, wherein the mole fraction of the first component of the semiconductor material in the at least one barrier layer is at least as great as in the n-side terminating layer.

4. The optoelectronic semiconductor body according to claim 1, wherein the mole fraction of the first component of the semiconductor material in the at least one barrier layer is at least as great as in the p-side terminating layer.

5. The optoelectronic semiconductor body according to claim 1, wherein the mole fraction of the first component of the semiconductor material in the n-side terminating layer, in the at least one barrier layer and in the p-side terminating layer is of equal magnitude.

6. An optoelectronic semiconductor body, which contains a semiconductor material having a first component and a second component different from the first component, the semiconductor body comprising a single quantum well structure arranged between an n-conducting layer and a p-conducting layer, the single quantum well structure consisting of:
one single quantum well layer;
an n-side terminating layer, which adjoins the quantum well layer and the n-conducting layer; and
a p-side terminating layer, which is arranged between the quantum well layer and the p-conducting layer and adjoins the quantum well layer,
wherein the mole fraction of the first component of the semiconductor material
of the quantum wall layer is greater than in the n-side terminating layer and in the p-side terminating layer, and
is greater in the n-side terminating layer than in the n-conducting layer and is greater in the p-side terminating layer than in the p-conducting layer.

7. The optoelectronic semiconductor body according to claim 6, wherein the n-conducting layer comprises a p-side boundary zone, which adjoins an n-side boundary zone of the n-side terminating layer, and the p-side boundary zone of the n-conducting layer and the n-side boundary zone of the n-side terminating layer are doped with an n-dopant.

8. The optoelectronic semiconductor body according to claim 6, wherein the n-side terminating layer comprises a p-side boundary zone, which directly adjoins the layer stack or the single quantum well layer and which is nominally undoped.

9. The optoelectronic semiconductor body according to claim 1, wherein the n-side terminating layer has a layer thickness of greater than or equal to 10 nm.

10. The optoelectronic semiconductor body according to claim 7, wherein the p-side boundary zone of the n-side terminating layer has a layer thickness of greater than or equal to 10 nm.

11. The optoelectronic semiconductor body according to claim 1, wherein the first component of the semiconductor material is formed of In and the second component of the semiconductor material contains nitrogen and at least one material from the group consisting of Al and Ga.

12. The optoelectronic semiconductor body according to claim 11, wherein the semiconductor material is InxAlyGal-x-yN, with 0≦x≦1, 0≦y≦1 and x+y≦1, and the first component formed of In has a fraction x≧0.05 in the n-side terminating layer.

13. The optoelectronic semiconductor body according to claim 1, wherein the n-conducting layer lacks the first component of the semiconductor material.

14. The optoelectronic semiconductor body according to claim 2, wherein the n-dopant in the p-side boundary zone of the n-conducting layer and in the n-side boundary zone of the n-side terminating layer is present in a concentration of greater than or equal to 5×1018 atoms/cm³.

15. The optoelectronic semiconductor body according to claim 1, wherein the mole fraction of the first component increases continuously or in a number of steps within the n-side terminating layer, in particular within the n-side boundary zone of the n-side terminating layer, in the direction away from the n-conducting layer.

16. An optoelectronic semiconductor body, which contains a semiconductor material having a first component and a second component different from the first component, the semiconductor body comprising a multiple quantum well structure arranged between an n-conducting layer and a p-conducting layer, the multiple quantum well structure consisting of:
a layer stack, which consists of a plurality of quantum well layers and at least one barrier layer, one barrier layer being arranged between each pair of successive quantum wall layers, which barrier layer adjoins both quantum wall layers;
an n-side terminating layer, which adjoins the layer stack and the n-conducting layer; and
a p-side terminating layer, which is arranged between the layer stack and the p-conducting layer and adjoins the layer stack,
wherein the first component of the semiconductor material is formed of In and the second component of the semiconductor material contains nitrogen and at least one material from the group consisting of Al and Ga,
wherein the mole fraction of the first component of the semiconductor material is greater in each of the quantum wall layers than in the n-side terminating layer, in the at least one barrier layer and in the p-side terminating layer,
wherein the mole fraction of the first component of the semiconductor material is greater in the n-side terminating layer than in the n-conducting layer and is greater in the p-side terminating layer than in the p-conducting layer, and
the n-conducting layer comprises a p-side boundary zone, which adjoins an n-side boundary zone of the n-side terminating layer, and the p-side boundary zone of the n-conducting layer and the n-side boundary zone of the n-side terminating layer are doped with an n-dopant.

17. The optoelectronic semiconductor body according to claim 16, wherein the n-side terminating layer comprises a p-side boundary zone, which directly adjoins the layer stack or the single quantum well layer and which is nominally undoped.

18. The optoelectronic semiconductor body according to claim 16, wherein the p-side boundary zone of the n-side terminating layer has a layer thickness of greater than or equal to 10 nm.

19. The optoelectronic semiconductor body according to claim 16, wherein the n-dopant in the p-side boundary zone of the n-conducting layer and in the n-side boundary zone of the n-side terminating layer is present in a concentration of greater than or equal to 5×10¹⁸ atoms/cm³.

20. The optoelectronic semiconductor body according to claim 6, wherein the first component of the semiconductor material is formed of In and the second component of the semiconductor material contains nitrogen and at least one material from the group consisting of Al and Ga.
